(19) United States
(12) Patent Application Publication
(10) Pub. No.: US 2010/0254056 A1
(43) Pub. Date: Oct. 7, 2010

(54) EFFICIENT METHOD FOR CALCULATING THE DOT PRODUCT IN FAULT DETECTION ALGORITHMS

(75) Inventors: Krishnaswamy Gururaj Narendra, Winnipeg (CA); Glenn William Swift, Winnipeg (CA); David James Fedirchuk, Ile De Chenes (CA); Arthur Neufeld, Winnipeg (CA)

Correspondence Address: SONNENSCHEIN NATH & ROSENTHAL LLP, P.O. BOX 061080, WACKER DRIVE STATION, WILLIS TOWER, CHICAGO, IL, 60606-1080, US

(73) Assignee: ERLPhase Power Technologies Limited, Winnipeg (CA)

(21) Appl. No.: 12/753,020

(22) Filed: Apr. 1, 2010

Related U.S. Application Data
(60) Provisional application No. 61/165,651, filed on Apr. 1, 2009.

(51) Int. Cl. H02H 3/00; G01R 31/02

(52) U.S. Cl. 361/87; 324/537

(57) ABSTRACT

A method of electrical fault determination using the phase angle information of all the currents entering and leaving a protection zone, to determine whether a fault, if any, is internal or external to the protection zone.

### CROSS REFERENCE TO RELATED APPLICATIONS

This application claims the benefit of priority of U.S. Provisional Patent Application No. 61/165,651 filed Apr. 1, 2009, which is incorporated herein by reference in its entirety.

### FIELD OF THE INVENTION

The present invention relates generally to transmission of electricity. More particularly, the present invention relates to fault determination in the transmission of electricity.

### BACKGROUND OF THE INVENTION

The primary goal of any electrical power utility is to provide uninterrupted power to the end consumer. In order to achieve this, utilities depend on reliable protection devices to provide protection to power system apparatus and elements such as generators, transformers, bus bars, overhead transmission lines, under abnormal or fault conditions. Reliability is a compromise between security and dependability. The front end measurement system of the modern Micro Processor based Relays is subjected to a number of challenges such as noise, extreme nonlinearities due to saturation and harmonics of the signals. To protect an individual power system element by identifying the type of fault and isolating it from the rest of the system is not trivial.

A number of techniques have been developed such as symmetrical components to identify different fault types. Most of these techniques provide solutions to protect individual power system components. In some cases, elements such as transmission lines or transformers can be connected together to form a power system bus. The information about the currents from each of the elements connected to the bus can be used to determine if a fault has taken place on the bus itself or whether a fault has occurred on one or more of the elements connected to the bus. The requirement is to remove a faulted element from the power system by itself and not affect the remaining elements. If the fault is determined to be on the bus itself, it being a common component to all the connected elements, the correct required action would be to remove all elements connected to that bus in order to clear this fault from the power system. The motivation for this innovation is in a new way of extracting the information from the current phasors of each of the elements connected to the bus in order to provide a definite determination as to whether a given system fault is within a given bus zone or whether the fault is on one or more of the elements connected to the bus.

It is, therefore, desirable to provide a new and improved method of fault determination.

### SUMMARY OF THE INVENTION

In a first aspect, the present invention provides a method of detecting a fault condition within or outside a zone of protection by repeatedly selecting and determining the dot product for pairs of current phasors until all such phasors entering the zone of protection are compared.

In a further aspect, the present invention provides a method of detecting a fault condition between a first current phasor Iᵢ and a second current phasor Iⱼ, including determining Iᵢ·Iⱼ, determining |Iᵢ||Iⱼ| cos(θₒ ); evaluating Iᵢ·Iⱼ<|I_{i||I}_{j| cos(θ}ₒ); and triggering a true action if true or a false action if false. In an embodiment of the present invention, this is repeated for each phasor pair. In an embodiment of the present invention, the true action includes indicating the absence of internal fault. In an embodiment of the present invention, the false action includes indicating an internal fault.

In an embodiment of the present invention, the method further includes first selecting a threshold current magnitude t₁, comparing each current phasor to the threshold current magnitude, and triggering a trivial reject if no phasor is longer than the threshold t₁.

In an embodiment of the present invention, the method further includes providing a reference current phasor, identifying a fault current phasor, determining the dot product of the reference current phasor and the fault current phasor; and identifying a directional factor, indicating the direction of the fault from the dot product. In an embodiment of the present invention, the method further includes supervising the operation of an overcurrent protector using the directional factor.

In a further aspect, the present invention provides a system for fault detection including means for detecting a first current phasor Iᵢ, and a second current phasor Iⱼ, means for calculating Iᵢ·Iⱼ, means for calculating |Iᵢ||Iⱼ| cos(θₒ), and, means for indicating a fault condition if |Iᵢ||Iⱼ| cos(θₒ) is greater than Iᵢ·Iⱼ.

In an embodiment of the present invention, the system further includes means for generating a fault trip signal adapted to trip a protective device. In an embodiment of the present invention, the protective device is a circuit breaker. In an embodiment of the present invention, the protective device is a relay.

In a further aspect, the present invention provides a breaker having fault detection including means for detecting a first current phasor Iᵢ, and a second current phasor Iⱼ, means for calculating Iᵢ·Iⱼ, means for calculating |Iᵢ||Iⱼ| cos(θₒ), and means for tripping the breaker if |Iᵢ||Iⱼ| cos(θₒ) is greater than Iᵢ·Iⱼ.

In a further aspect, the present invention provides a relay having fault detection including means for detecting a first current phasor Iᵢ; and a second current phasor Iⱼ, means for calculating Iᵢ·Iⱼ, means for calculating |Iᵢ||Iⱼ| cos(θₒ), and means for tripping the breaker if |Iᵢ||Iⱼ| cos(θₒ) is greater than Iᵢ·Iⱼ.

Use of the rapid deployment of the DOT product on current vectors can establish if a fault exists in the zone defined by the location of the current sources. The current leaving and entering this zone must add to zero if no fault is present. This summation of current involves the addition of all current sources or loads and involves measuring the magnitudes and the angles of the currents, and the DOT product does this.

In some other instances, it is desirable to know the phasor relationship between voltage and current phasors during fault conditions. Usually one phasor is a reference voltage or current phasor that can be compared with the fault current phasor. A positive DOT product for this condition indicates that the fault is in the direction of the reference quantity. This directional factor is also sometimes used to supervise the operation of other devices such as overcurrent protections.

Using the present and the recent past current through a breaker and performing the DOT product on these currents, a decision can be made as to whether an impeding power swing will become unstable or whether it will retain synchronization. Opening the breaker of a line that will become unstable can cause catastrophic failure of the breaker that can cause additional equipment damage in the substation and can create a significant safety concern to any personnel in the area. Opening the line at a different location and allowing this breaker to remain closed for this type of situation can save the equipment from damage.

High voltage breakers may or may not be rated to interrupt capacitive current. If a breaker that is not capacitive rated is called upon to open, say a transmission line that can have significant capacitive line charging current, breaker damage may occur. One way to prevent breaker damage is to compare the phase angle of the current and the breaker as seen by the breaker. If the DOT product becomes zero, where current I leads voltage V by 90 degrees, the trip of the breaker (and corresponding potential damage to same) can be prevented.

In many protection algorithms, the projection of one vector on another is used to determine if a fault is inside or outside a zone. The line distance mho characteristic is one example of this. For this application, the phase angle of one phasor called the operating quantity is compared with another phasor called the restraint quantity. For a mho characteristic that is circular in nature, the angle between the operating and the restraint phasors must be 90 degrees or less to be in the trip region. For a three phase line, this comparison is done for all phases for all possible fault combinations. This type of calculation is typically done 24 times every 2 ms or typically 11,520 times per second, so any reduction in processing time can lead to better and less expensive protection.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

Embodiments of the present invention will now be described, by way of example only, with reference to the attached Figures, wherein:

FIG. 1 is a schematic of a dot product of the present invention, used to determine whether a fault is external or internal;

FIG. 2 is a schematic of a trivial reject and external fault situation; and

FIG. 3 is a schematic of a trivial reject and internal fault situation.

### DETAILED DESCRIPTION

Generally, the present invention provides a method and system for fault determination and location.

The inventors have developed a unique method to use power system current phase angles to determine if a fault exists within a defined power system zone.

This technique uses the phase information of power system currents without the need for any other reference quantities to see if power system faults are within a zone or if they are outside this zone. This technique's decision process uses a phase angle grouping technique that is very robust and is immune to current transformer (CT) effects such as saturation, DC offsets or harmonics.

The methodology can be applied on its own or can be combined with other logic to protect transformers, busses, lines or any other piece of power system equipment where current phase angles can be measured.

The innovation will be described in the subsequent section pertaining to Bus differential protection.

Existing Differential Protection Method

The differential protection method currently used is the percentage differential protection. This method works based on the comparison of the total operating current sum (magnitude of the vector sum of all the current phasors) versus the restraining current, which is the sum of the magnitudes of all the current phasors entering the protection zone of the equipment to be protected, such as a bus, transformer, generator or any other equipment. This method involves knowledge of the loading and charging current to set the minimum operating current pickup levels. In many cases, this pickup level is either under or over estimated. Optimal setting of this parameter involves careful study of the existing power system and to an extent the future loading pattern.

Disadvantages of Existing Method

There are situations where current from a faulted element (connected to the bus) may cause saturation to occur in the element's main CTs or in the CTs used within the protective relay.

This saturation is dependent upon factors such as fault magnitude, type of fault, time of fault inception and CT characteristics. The saturation in the CTs can occur in the first cycle, or several cycles after the inception of the fault due to a “late induction” effect caused by a slowly decaying DC component added to the sinusoidal AC component. This scenario is possible near the protection zone where a high X/R ratio is present.

Conventional differential protection may mis-operate for the above late saturation effect. Today, the method used by saturation detectors of tracking the differential current trajectory (IO and IR) during late saturation cannot guarantee security in many circumstances/contingencies. In many cases the DC component induced CT saturation produces enough operating current (IO) to bring the differential trajectory into the trip zone, but will not produce enough restraint current (IR) to cause the late CT saturation detector to block the trip. The present invention, which may be implemented by firmware or other implementation addresses this issue and enhances the 87B security by means of differential trajectory tracking (IO & IR) and providing some fixed additional delay, without sacrificing the speed of operation for an internal fault.

The inrush current caused by the transformer energization contains significant 2nd harmonics contents. The use of 2nd harmonics restraint can effectively prevent the device from falsely tripping during transformer energization. However, the inrush currents and the associated 2nd harmonic contents are not evenly distributed on each phase (because of the different points on wave for each phase voltage when the transformer is switched in, and also the different residual flux on each phase). In most cases, at least 2 phase currents will contain significant 2nd harmonic contents because of the use of the delta-current inside the relay.

Delta Phase Algorithm Problem

The Delta Phase Algorithm, as written, relies on the difference in phase angles between several current phasors. Calculating the phase angles, however, requires a relatively expensive “a tan2(y,x)” calculation even on an advanced microprocessor. Usually, the calculations should be carried out on 18 to 24 sets of inputs times the three phases, which would result in 54 or 72 inputs, and the combinations of comparing each input with others. Once the phase angle of the phasors has been calculated, then the difference between each pair of the 6 phasors (per phase) must be computed. This translates to 15 phase difference pairs per bus, for a total of 45 phase differences. The phase differences must further be normalized, since two phasors at angles of +10° and +350° respectively, are only 20° apart, not 340°.

Delta Phase Angle Fault Determination

The method of the present invention uses the phase angle information of all the currents entering and leaving the protection zone effectively to determine whether the fault is internal or external to the power system element to be protected. Since this technique is not sensitive in principal to the operating current settings, or magnitude of the sum of the currents, the method allows a very definite and secure method of determining whether a fault is internal or external to a defined protection zone. This protection zone is defined by the location of the area between all element CTs that form this differential zone.

In principle, all currents from elements connected to a bus structure must obey the concept of conservation of current. The currents entering and leaving a differentially protected zone must add to zero if no fault within this differential zone is present.

In actual differential installations high fault currents and introduction of DC offsets can cause current measuring CTs to saturate, sometimes quickly and sometimes slowly. Techniques that use current magnitude summations can have security issues during these situations and as a result can cause mis-operations, where CT transformations occur.

The present method uses the phase angle of the currents to determine which currents are contributing to the currents within a differential zone and which elements have currents taking current away from the protection zone. It has been determined that phase angle values do not change significantly during CT saturation making phase angle criteria a means to determine system fault location based on phase angle measurement very reliable and secure. The proposed technique uses grouping of element current phase angles to determine faults that are external or external to protection zones. The phase angle grouping technique proposed does not need any other inputs other than element currents to make phase angle decisions. The changes in phase angles of all current inputs are monitored and decisions are made on this basis.

In practice, the phase angle algorithm can be used alone or in conjunction with other differential based techniques as need arises.

The basic concept used is to compute the dot product of two phasors at a time until all phasors at the given zone of protection are compared. The decision used is to find whether the resulting dot product is positive or negative, which indicates that the fault is within the zone of protection (internal fault) or outside the zone (external fault).

For two current phasors or vectors IA & IB, the dot product is IA·IB=|IA||IB| cos(theta)=IAₓ*IBₓ+IA_{y}*IBy, where the term cos(theta) directly indicates the phase difference between the two vectors. The cosine of the phase difference, cos(theta), decreases as the phase difference, theta, increases. Specifically, for theta<90°, cos(theta) is positive; for theta>90°, cos(theta) is negative.

To determine if the phase difference, θ, between two vectors is greater than a specific set-point angle θo, we can instead test if cos(θ)<cos(θo), where cos(θ) is given by A·B/(|A|B|). Since cos(θo) is a constant, only evaluated once, no expensive transcendental functions are required after the relay has been initialized. Further, since |A| and |B| are both guaranteed to be positive, the inequality can be rewritten as: A·B<|A||B| cos(θo), eliminating the division operation.

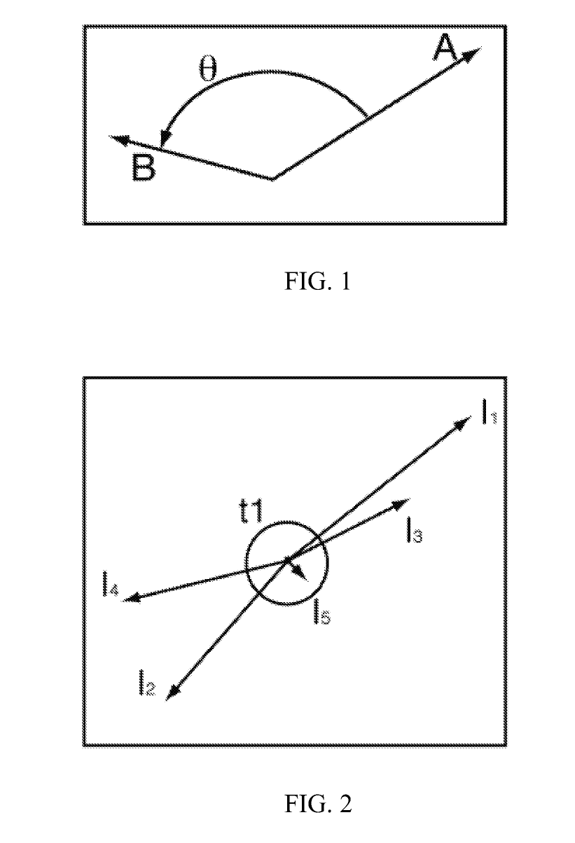

Referring to FIG. 1, a dot product may be used to detect external or internal fault. Instead of computing each phasor's phase angle, and then differencing pairs of phase angles (and subsequently normalizing the results), an indication of the difference in phase angles can be computed directly, using the dot product. For two vectors A & B, the dot product is A·B=|A||B| cos(θ)=Aₓ·Bₓ+A_{y}·B_{y}, where the term cos(θ) directly indicates the phase difference between the two vectors. The cosine of the phase difference, cos(θ), decreased as the phase difference, θ, increases. Specifically, for θ<90°, cos(θ) is positive; for θ>90°, cos(θ) is negative.

To determine if the phase difference, θ, between two vectors is greater than a specific set-point angle θₒ, we can instead test if cos(θ)<cos(θₒ), where cos(θ) is given by A·B/(|A||B|). Since cos(θₒ) is a constant, only evaluated once, no expensive transcendental functions are required after the relay has been initialized. Further, since |A| and |B| are both guaranteed to be positive, the inequality can be rewritten as: A·B<|A||B| cos(θₒ), eliminating the division operation.

Once all angle comparisons are made, the current vectors are grouped according to their relative angles as compared to the other current vectors.

During normal conditions within a protection zone, currents will flow into the zone and leave the zone. This will be reflected by indicating that at least two current vector angles will be greater than 90 degrees from each other.

On the other hand, during a fault within the protected zone, all current contributing elements connected to the zone will line up with each other with angles less than 90 degrees apart.

For faults outside the protected zone, unfaulted elements contributing to the fault will all line up to contribute to the fault with their respective fault angles and the element with the external fault will exhibit a current phase angle approximately directly opposite to these. Having at least one current phase angle at an angle greater than 90 degrees from any other current phase angle within a protected zone is a clear indication that the fault is external to the protected zone. This effect is present even if the external fault on one of the elements exhibits CT saturation as phase angle on a saturated CT does not change significantly.

Threshold Parameters

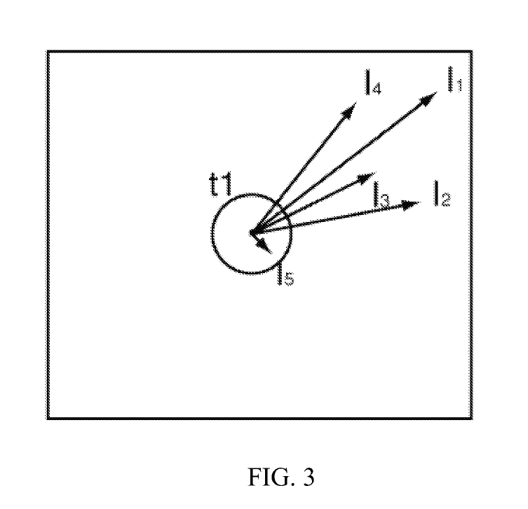

Since the phase angles become erratic as the phasor magnitude approaches zero, any phasor with a magnitude less than a selected or predetermined threshold value, t₁ will be excluded from this algorithm. The threshold value t₁ may be some relatively small quantity, for example 0.1A. Furthermore, the threshold value t₁ should be larger than the charging current for the line, in order to exclude lines where the breaker at the far end has been opened (e.g., Ioₘᵢₙ). Referring to FIGS. 2 and 3, I₅ are shown below threshold t₁.

Any phase angle difference greater than a selected or predetermined phase angle difference value θₒ indicates there is no internal fault (for example,90°).

Algorithm (Executed Per Phase)

The magnitude of all current phasors are examined. If no phasor is longer than threshold, t₁, then there is no internal fault. This is referred to as ‘Trivial Reject’.

If a phasor pair has a sufficiently large phase angle-difference, then for each pair, Iᵢ and Iⱼ, where i>j, |Iᵢ|>t₁ and |Iⱼ|>t₁:

Determine: Iᵢ·Iⱼ(that is, Iᵢdot Iⱼ)

Determine: |Iᵢ||Iⱼ| cos(θₒ)

Evaluate: Iᵢ·Iⱼ<|Iᵢ||Iⱼ| cos(θₒ). If true, then there is no internal fault. Referring to FIG. 2, an external fault situation is shown. Referring to FIG. 3, an internal fault situation is shown.

In the event that there is an internal fault, an indicator may be activated to alert an operator of the fault condition, or in the case of a circuit breaker or protection relay, the circuit breaker or relay may be tripped.

In one embodiment, the method of the present invention includes an algorithm to protect electrical power systems.

In method or apparatus form, the present invention may be embodied in a wide variety of applications, including, but not limited to protection relays, circuit breakers, current transformers, or voltage transformers (or other such protection apparatus or methods known to one ordinarily skilled in the art).

In the preceding description, the method and apparatus have been described using current phasors. One skilled in the art recognizes that the method and apparatus may utilize voltage phasors instead of, or in combination with, current phasors.

In the preceding description, for purposes of explanation, numerous details are set forth in order to provide a thorough understanding of the embodiments of the invention. However, it will be apparent to one skilled in the art that these specific details are not required in order to practice the invention. In other instances, well-known electrical structures and circuits are shown in block diagram form in order not to obscure the invention.

The above-described embodiments of the invention are intended to be examples only. Alterations, modifications and variations can be effected to the particular embodiments by those of skill in the art without departing from the scope of the invention, which is defined solely by the claims appended hereto.

What is claimed is:

1. A method of detecting a fault condition inside or outside a zone of protection comprising repeatedly selecting and determining the dot product for pairs of untested phasors until all phasors at the zone of protection are compared.

2. A method of detecting a fault condition between a first current phasor I ᵢ and a second current phasor I ⱼ, comprising:
a. determining Iᵢ·Iⱼ;
b. determining |Iᵢ||Iⱼ| cos(θₒ);
c. evaluating Iᵢ·Iⱼ<|Iᵢ||Iⱼ| cos(θₒ); and triggering a true action if true or a false action if false.

3. The method of claim 2, further comprising:
a. first selecting a threshold current magnitude t₁:
b. comparing each current phasor to the threshold current magnitude; and
c. triggering a trivial reject if no phasor is longer than the threshold, t₁.

4. The method of claim 2, further comprising:
a. providing a reference current phasor;
b. identifying a fault current phasor;
c. determining the dot product of the reference current phasor and the fault current phasor; and
d. identifying a directional factor, indicating the direction of the fault from the dot product.

5. The method of claim 4, further comprising supervising the operation of an overcurrent protector using the directional factor.

6. The method of claim 2, repeated for all phasor pairs.

7. The method of claim 2, the true action comprising indicating no internal fault.

8. The method of claim 2, the false action comprising indicating an internal fault.

9. A system for fault detection comprising:
a. means for detecting a first current phasor Iᵢ and a second current phasor Iⱼ;
b. means for calculating Iᵢ·Iⱼ;
c. means for calculating |Iᵢ||Iⱼ| cos(θₒ) and
d. means for indicating a fault condition if |Iᵢ||Iⱼ| cos(θₒ) is greater than Iᵢ·Iⱼ.

10. The system of claim 9, further comprising means for generating a fault trip signal adapted to trip a protective device.

11. The system of claim 10, the protective device a breaker or a relay.

12. A breaker having fault detection comprising:
a. means for detecting a first current phasor Iᵢ and a second current phasor Iⱼ;
b. means for calculating Iᵢ·Iⱼ;
c. means for calculating |Iᵢ||Iⱼ| cos(θₒ); and
d. means for tripping the breaker if |Iᵢ||Iⱼ| cos(θₒ) is greater than Iᵢ·Iⱼ.

13. A relay having fault detection comprising:
a. means for detecting a first current phasor Iᵢ and a second current phasor Iⱼ;
b. means for calculating Iᵢ·Iⱼ;
c. means for calculating |Iᵢ||Iⱼ| cos(θₒ): and
d. means for tripping the breaker if |Iᵢ||Iⱼ| cos(θₒ) is greater than Iᵢ·Iⱼ.
